(19) United States
(12) Patent Application Publication
(10) Pub. No.: US 2005/0035437 A1
(43) Pub. Date: Feb. 17, 2005

(54) Package part and method of manufacturing the part

(76) Inventor: Yoshishige Yoshikawa, Kashihara-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/502,188

(22) PCT Filed: Jan. 22, 2003
(86) PCT No.: PCT/JP03/00515

(30) Foreign Application Priority Data
Jan. 23, 2002 (JP) 2002-013887
Jan. 23, 2002 (JP) 2002-013888
Jan. 23, 2002 (JP) 2002-013889

(51) Int. Cl. H01L 23/02

(52) U.S. Cl. 257/678

(57) ABSTRACT

A packaged component according to one of the embodiments of the present invention includes a function chip having a chip surface, a volume-changing material layer formed over the function chip, and a seating member for sealing the function chip and the volume-changing material layer. At least a part of the chip surface of the function chip is spaced from the volume-changing material layer. Further, the function chip has a peripheral edge portion, and the sealing member supports the function chip at the peripheral edge portion thereof.

### BACKGROUND OF THE INVENTION

1) Technical field of the Invention

The present invention relates to a packaged component having one or more chips sealed by insulating resin material.

2) Description of Related Arts

A communication devices such as a cellular phone, a cordless phone, and a transceiver incorporate a packaged component having a function chip such as a SAW filter and a quarts oscillator sealed by insulating resin material. The chip includes pectinate (comb-like) electrodes of aluminum on a chip surface of piezoelectric substrate of quartz crystal. A signal to be filtered is transmitted as a surface acoustic wave on and near the chip surface of the function chip. Therefore, it is required that the chip surface supporting the pectinate electrodes contacts gas. Therefore, as illustrated in FIG. 7, a conventional function chip 21 is structured within a package 22. The package 22 includes, in general, a case 23 made of ceramics, and a cap 24 made of metal that is fixed within the case 23 by brazing or welding. This function chip has drawbacks increasing a packaging cost and requiring a brazing or welding step in the manufacturing process thereof.

In another type of conventional devices as shown in FIG. 12, an integrated circuit device having a radio communication function includes a semiconductor integrated circuitry 62, a SAW filter 63, and a quartz oscillator 64 on a printed circuit board 61. In the device, the semiconductor integrated circuitry 62 is made by sealing a semiconductor integrated circuit chip with insulating resin material. Also, the SAW filter 63 and the quartz oscillator 64 are formed by accommodating piezoelectric chips within packages of ceramics. Thus, each of those elements requires a respective packaging step so that the manufacturing process of the integrated circuit device in total requires various steps for those elements.

Also, as illustrated in FIG. 20, another semiconductor integrated circuit chip 101 has been proposed, having a coil 102 on the surface thereof, which serves an inductance of a LC resonator in a high-frequency oscillator. In general, the chip 101 is sealed within insulating resin material and electrically connected with external terminals supported thereby. However, in the integrated circuit chip so structured, the coil is mounted on a silicon substrate of semiconductor, which is not made of insulating material and has a resistance component. Thus, the high-frequency signal is partially absorbed in the silicon substrate to damp its amplitude, thereby reducing the Q-value of the coil. Therefore, the packaged component containing the chip has drawbacks of substantial noise and reduced output level of oscillating signal, when used as a high-frequency oscillator.

### SUMMARY OF THE INVENTION

To solve those drawbacks, a package according to the present invention includes a function chip, a volume-shrinking material layer formed on a surface of said function chip, and a sealing material. A volume of the volume-shrinking material layer is reduced after the function chip and the volume-shrinking material layer are sealed with the sealing material so that a space enclosing void or gas is defined between a surface of the function chip and the volume-shrinking material layer.

According to another aspect of the invention, the volume-shrinking material layer is made of heat-reactive material of which volume is reduced when it is cooled after heated, and the volume of the volume-shrinking material layer is reduced by cooling the volume-shrinking material layer after the function chip and the volume-shrinking material layer are heated while being sealed with the sealing material, or after the function chip and the volume-shrinking material layer are sealed and then heated.

According to another aspect of the invention, the volume-shrinking material layer is made of electromagnetic reactive material of which volume is reduced when it is exposed to electromagnetic wave, and the volume of the volume-shrinking material layer is reduced by radiating electromagnetic wave to the volume-shrinking material layer after the function chip and the volume-shrinking material layer are sealed with the sealing material.

According to another aspect of the invention, the volume-shrinking material layer is made of chemically reactive material of which volume is reduced when it reacts with a chemical compound contained in the sealing material, and the volume of the volume-shrinking material layer is reduced by allowing the volume-shrinking material layer to react with the chemical compound contained in the sealing material while the function chip and the volume-shrinking material layer are being sealed with the sealing material.

Another package according to the preset invention includes a function chip, a volume-shrinking material layer formed on a surface of said function chip, the volume-expanding material layer having a characteristic that a volume thereof is increased when heated, and a sealing material, wherein the volume-expanding material layer is cooled after the function chip and the volume-expanding material layer are sealed with the sealing material while being heated so that a space enclosing void or gas is defined between a surface of the function chip and the volume-expanding material layer.

According to another aspect of the invention, the package further includes an adhesive layer formed between the volume-shrinking material layer/the volume-expanding material layer and the sealing material for attaching the volume-shrinking material layer/the volume-expanding material layer with the sealing material. The volume-shrinking material layer/the volume-expanding material layer and the sealing material are designed such that the sealing material is prevented from being separated from the volume-shrinking material layer/the volume-expanding material layer, when the volume of the volume-shrinking material layer/the volume-expanding material layer is reduced to define the space between the function chip and the volume-shrinking material layer/the volume-expanding material layer.

According to another aspect of the invention, the package further includes a releasing agent layer formed between the volume-shrinking material layer/the volume-expanding material layer and the sealing material for facilitating separation of the function chip from the volume-shrinking material layer/the volume-expanding material layer. The function chip separates from the volume-shrinking material layer/the volume-expanding material layer when the volume of the volume-shrinking material layer/the volume-expanding material layer is reduced to define the space between the function chip and the volume-shrinking material layer/the volume-expanding material layer.

Another package according to the invention, a package includes a function chip, first and second sealing materials, and a volume-shrinking material layer. The function chip is sealed with the first sealing material, the volume-shrinking material layer is formed on a whole or partial region of the first sealing material, and the first sealing material and the volume-shrinking material layer are encompassed by and sealed with the second sealing material. Also, a volume of the volume-shrinking material layer is reduced to deform the first sealing material in the whole or partial region towards the volume-shrinking material layer in response to the shrinkage of the volume-shrinking material layer so that a space enclosing void or gas is defined between the function chip and the first sealing material.

According to another aspect of the invention, the volume-shrinking material layer is made of heat-reactive material of which volume is reduced when it is cooled after heated, and the volume of the volume-shrinking material layer is reduced by cooling the volume-shrinking material layer after the volume-shrinking material layer is heated while being sealed with the first sealing material, or after the volume-shrinking material layer is sealed with the second sealing material and then heated.

According to another aspect of the invention, the volume-shrinking material layer is made of electromagnetic reactive material of which volume is reduced when it is exposed to electromagnetic wave, and the volume of the volume-shrinking material layer is reduced after the volume-shrinking material layer is sealed with the second sealing material.

According to another aspect of the invention, the volume-shrinking material layer is made of chemically reactive material of which volume is reduced when it reacts with a chemical compound contained in the sealing material, and the volume of the volume-shrinking material layer is reduced by allowing the volume-shrinking material layer to react with the chemical compound contained in the second sealing material while being sealed with the second sealing material.

Another package according to the invention includes a function chip, first and second sealing materials, a volume-expanding material layer having a characteristic that a volume thereof is increased when heated. Also, the function chip is sealed with the first sealing material, the volume-expanding material layer is formed on a whole or partial region of the first sealing material, and the first sealing material and the volume-expanding material layer are encompassed by and sealed with the second sealing material when heated, and the volume-expanding material layer is cooled to deform the first sealing material in the whole or partial region towards the volume-expanding material layer so that a space enclosing void or gas is defined between the function chip and the first sealing material.

According to another aspect of the invention, the package further includes a first adhesive layer formed between the volume-shrinking material layer/the volume-expanding material layer and the first sealing material for attaching the volume-shrinking material layer/the volume-expanding material layer with the first sealing material, a second adhesive layer formed between the volume-shrinking material layer/the volume-expanding material layer and the second sealing material for attaching the volume-shrinking material layer/the volume-expanding material layer with the second sealing material. Also, the volume-shrinking material layer/the volume-expanding material layer and the first and second sealing materials are designed such that the first and second sealing materials are prevented from being separated from the volume-shrinking material layer/the volume-expanding material layer, when the volume of the volume-shrinking material layer/the volume-expanding material layer is reduced.

According to another aspect of the invention, the package further includes a releasing agent layer formed between the function chip and the first sealing material for facilitating separation of the function chip from the first sealing material. Also, the function chip separates from the first sealing material when the volume of the volume-shrinking material layer/the volume-expanding material layer is reduced to define the space between the function chip and the first sealing material

An integrated circuitry according to the present invention includes an integrated circuit chip, a piezoelectric material chip having an electrode on a surface thereof, external connection terminals, a volume-shrinking material, a sealing material, and a volume-shrinking material layer formed of the volume-shrinking material on a whole or partial region of the piezoelectric material chip, Also, electrode pads on the surfaces of the integrated circuit chip and the piezoelectric material chip are electrically connected to the external connection terminals, and a volume of the volume-shrinking material layer is reduced after the integrated circuit chip, the piezoelectric material chip, the external connection terminals, and the volume-shrinking material layer are sealed with the sealing material so that a space enclosing void or gas is defined between the surface of the piezoelectric material chip and the volume-shrinking material layer.

In another aspect of the invention, the piezoelectric material chip includes a SAW filter chip and a quartz oscillator chip, and the volume-shrinking material layer is formed on regions where pectinate electrodes of the SAW filter chip and oscillating regions of the quartz oscillator chip are formed.

According to another aspect of the invention, a structure formed on a semiconductor integrated circuit chip, and a volume-shrinking material layer over the structure. Also, after the semiconductor integrated circuit chip and the volume-shrinking material layer are sealed with a sealing material, a volume of the volume-shrinking material layer is reduced so that the structure separates and moves away from a surface of the semiconductor integrated circuit chip.

According to another aspect of the invention, the structure is a coil pattern of metal, and a whole or partial region of the coil pattern attaches with the volume-shrinking material layer so that the whole or partial region of the coil pattern separates and moves away from the semiconductor integrated circuit chip, thereby to realize a desired characteristic.

A manufacturing process of a packaged component according to the present invention includes (a) preparing an element, (b) depositing a volume-changing member on at least a partial surface of the prepared element, (c) sealing the element and the volume-changing member with a sealing material, (d) shrinking the volume-changing member sealed with the sealing material to separate the volume-changing member from the partial surface of the element opposing thereto, thereby to define a space therebetween.

According to another aspect of the invention, the volume-changing member is made of material that shrinks when heated, and the step (d) is made by heating to shrink the volume-changing member.

According to another aspect of the invention, the volume-changing member is made of material that expands when heated. Also, the step (c) is made while the volume-changing member is heated for expansion, and the step (d) is made by cooling to shrink the volume-changing member heated in the step (c).

According to another aspect of the invention, the volume-changing member is made of material that shrinks when exposed to a electromagnetic wave, and the step (d) is made by radiating the electromagnetic wave to the volume-changing member.

According to another aspect of the invention, the step (b) includes applying a releasing agent between the volume-changing member and the partial surface of the element opposing thereto, applying the volume-changing member on the releasing agent, and applying an adhesive between the volume-changing member and the sealing material opposing thereto.

Another manufacturing process of a packaged component according to the present invention includes (a) preparing an element, (b) forming a cover layer on at least a partial surface of the prepared element, (c) depositing a volume-changing member on the cover layer, (d) sealing the element, the cover layer, and the volume-changing member with a sealing material, (e) shrinking the volume-changing member sealed with the sealing material to separate the volume-changing member from the partial surface of the element opposing thereto, thereby to define a space therebetween.

Another manufacturing process of a packaged component according to the present invention includes (a) preparing a semiconductor integrated circuit chip and a piezoelectric material chip, (b) arranging the semiconductor integrated circuit chip and the piezoelectric material chip at predetermined positions, (c) electrically connecting the semiconductor integrated circuit chip and the piezoelectric material chip to external connection terminals, (d) depositing a volume-changing member on at least a partial surface of the piezoelectric material chip, (e) sealing the semiconductor integrated circuit chip and the piezoelectric material chip with a sealing material after the steps (c) and(d), and (f) shrinking the volume-changing member sealed with the sealing material to define a space between the volume-changing member and the partial surface of the piezoelectric material chip.

Another manufacturing process of a packaged component according to the present invention includes (a) preparing a first element, (b) providing a second element on a surface of the first element, (c) depositing a volume-changing member on the second element,(d) sealing the first and second elements with a sealing material, and (e) shrinking the volume-changing member to separate the second element from the first element.

### BRIEF DESCRIPTION OF THE DRAWINGS

FIG. 1 is a cross sectional view of a packaged component of the first embodiment according to the present invention.

FIG. 2 is a cross sectional view illustrating a manufacturing process of the packaged component of FIG. 1.

FIG. 3 is a cross sectional view of a modified packaged component.

FIG. 4 is a cross sectional view of another modified packaged component.

FIG. 5 is a cross sectional view of a packaged component of the second embodiment.

FIG. 6 is a cross sectional view illustrating a manufacturing process of the packaged component of FIG. 5.

FIG. 7 is a cross sectional view of a packaged component according to the prior art.

FIG. 8 is a cross sectional view of a packaged component of the third embodiment.

FIG. 9 is a top plan view of a plurality of chips and lead frames contained within the packaged component of FIG. 8.

FIG. 10 is a cross sectional view taken along by X-X line of FIG. 8.

FIG. 11 is a cross sectional view taken along by XI-XI line of FIG. 8.

FIG. 12 is a top plan view of a conventional integrated circuit device.

FIG. 13 is a cross sectional view of a packaged component of the fourth embodiment.

FIG. 14 is a top plan view of a chip contained within the packaged component of FIG. 8.

FIG. 15 is a cross sectional view taken along by XV-XV line of FIG. 13.

FIG. 16 is a cross sectional view illustrating a manufacturing process of the packaged component of FIG. 13.

FIG. 17 is a cross sectional view of a packaged component of the fifth embodiment.

FIG. 18 is a top plan view of a chip contained within the packaged component of FIG. 17.

FIG. 19 is a perspective view of a coil formed on the chip of FIG. 17.

FIG. 20 is a cross sectional view of a packaged component according to the prior art.

### DETAILED DESCRIPTION OF THE PREFERRED EMBODIMENTS

Referring to the attached drawings, several embodiments of a packaged component and an integrated circuit device according to the present invention will be described in detail hereinafter. In those descriptions, although the terminology indicating the directions (for example, “up”, and “down”, and complex words thereof) are conveniently used just for clear understandings, it should not be interpreted that the scope of the present invention is not limited by those terminology, but defined by the attached claims.

Embodiment 1.

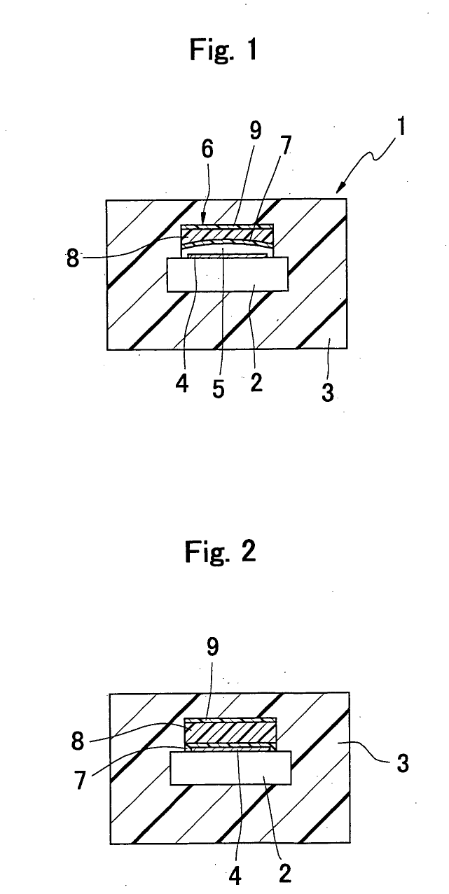

FIG. 1 is a cross sectional view of a packaged component according to the present invention. The packaged component, denoted by reference numeral 1 as a whole, includes a function chip 2 and a sealing material 3 of insulating resin material for sealing the function chip 2 therein. In the present embodiment, the chip 2 is a Surface Acoustic Wave filter (referred to simply as a “SAW” filter, hereinafter) having a crystal quartz substrate. The SAW filter 2 has a pectinate (comb-like) electrode 4 on either one of the surfaces (the upper surface in FIG. 1), in which the surface acoustic wave is excited on the surface, thereby causing resonance phenomena. The SAW filter is required to have the surface to contact gas in order to prevent the surface acoustic wave from being damped. For this reason, a space 5 is defined over the pectinate electrodes 4 by means of a manufacturing process as described below. A structure 6 used for defining the space 5 is remained within the sealing material 3 and over the pectinate electrodes 4.

The manufacturing process of the packaged component 1 as well as the space defining structure 6 will be described herein. Coated on the pectinate electrodes 4 of the prepared chip as illustrated in FIG. 2 is a releasing agent 7, on which a volume-changing material 8 and an adhesive 9 are subsequently provided. It should be noted that the electrode pads (not shown) of the chip 2 are electrically connected to external connection terminals or lead frames. Next, the chip 2 is set in a molding die (not shown) with the volume-changing material 8 provided on the electrode pads, then a sealing material 3 of insulating resin is injected into the molding die, so that the chip 2 is sealed.

The volume-changing material 8 used herein has a characteristic that when heated beyond a predetermined temperature, it changes the molecular structure and shrinks with the volume being reduced to approximately half of that before heated. Examples of the volume-changing material 8 include poly-ethylene, poly-propylene, vinyl chloride, acrylonitrile polymer, poly-norbornene, trans-poly-isoprene, stylene-butadiene copolymer, poly-urethane, and high-density poly-ethylene.

The releasing agent 7 and the volume-changing material 8 are selected such that the adhesion of the releasing agent 7 between the chip 2 and the volume-changing material 8 is less than that of the adhesive 9 between the volume-changing material 8 and the sealing material 3. In particular, the releasing agent 7 includes silicone-based polymer and fluoro-based polymer, and the adhesive 8 includes reactive polymer such as epoxy-based polymer, acryl-based polymer, urethane-based polymer, diene-based polymer, silicone-based polymer, polyester-based polymer, and cyanoacrylate-based polymer.

As above, the releasing agent 7, the volume-changing material 8, and the surface material of the chip 2 are selected such that when the volume-changing material 8 separates from the chip 2, the releasing agent 7 releases from the chip 2 and moves together with the volume-changing material 8. For example, where the chip surface in contact with the releasing agent 7 is composed of the electrodes (made of metal, e.g., cupper, aluminum, gold, platinum, and nickel) and insulating material (e.g., silicon nitride, silicon dioxide, and composition thereof), any one of the volume-changing materials and adhesives as mentioned above can be used.

After selecting materials for those as above, in the present manufacturing process, the packaged component 2 is heated up to the temperature in which the volume-changing material 8 shrinks until it has the volume approximately half of that before heated. Preferably, this heating step is achieved by keeping the sealing material 3 injected within the molding die at the temperature for a predetermined time period. This causes the volume-changing material 8 to shrink to the approximately half volume. As described above, since the adhesion of the releasing agent 7 between the chip 2 and the volume-changing material 8 is less than that of the adhesive 9 between the volume-changing material 8 and the adhesive 9, the shrinkage of the volume-changing material 8 breaks the layer of the releasing agent 7. Also, the releasing agent 7, the volume-changing material 8, and the surface material of the chip 2 are determined so that when the volume-changing material 8 is separated from the chip 2, the releasing agent 7 releases from the chip 2 and moves together with the volume-changing material 8. To this end, the releasing agent 7 separates from the chip 2 so that the void space is defined above the pectinate electrodes 4.

The volume-changing material used in the above embodiment changes the molecular structure and shrinks the volume to approximately half when heated over the predetermined temperature. Alternatively, another volume-changing material may be used in a modification of the embodiment, in which exposure of electromagnetic wave shrinks the volume or heats to shrink the volume of the volume-changing material. In the modification, since those materials reactive to the electromagnetic wave can selectively be heated, advantageously, thermal damage can substantially be eliminated to the other elements of the packaged component, such as the chip and sealing material. Also, the modification finishes the shrinking step of the volume-changing material more quickly by using the high-energy electromagnetic wave.

In another modification, chemically reacting material may be used as another volume-changing material, which reacts with the sealing material or chemical compound in the sealing material to shrink the volume. This modification eliminates the additional redundant step to heat the volume-changing material. Also, such chemical compound may be disposed only particular local region of the sealing material so that the volume-changing material in contact with the local region thereof can selectively react with the chemical compound to shrink the volume.

Instead of the volume-changing material that shrinks when heated, another volume-changing material can be used, which expands the volume when heated. When such a volume-changing material is used, the molding step is performed under high temperature, which causes the volume-changing material to expand and have an increased volume. Then, the sealing material cools down below the melting point thereby to congeal. As the sealing material and the volume-changing material further cool down, the volume-changing material shrinks the volume to define the space therebetween. Therefore, according to the present process, the space is defined during the molding step, thereby simplifying the manufacturing process as a whole.

As described above, the releasing agent is provided between the volume-changing material and the chip, thus, an interface member between the volume-changing material and the chip is the releasing agent. Also, the adhesive is provided between the volume-changing material and the sealing material, thus, another interface member between the volume-changing material and the sealing material is the adhesive. However, either one or both of the releasing agent and the adhesive can be eliminated. For example, if the releasing agent is eliminated, it is required that the adhesion between the chip and the volume-changing material is less than that between the volume-changing material and the sealing material, or that between the adhesive and the volume-changing material/the sealing material. Thus, the volume-changing material and the sealing material are selected so as to meet the aforementioned condition for adhesion. If the adhesive is eliminated, the adhesion between the volume-changing material and the sealing material is greater than that between the chip and the releasing agent, or that between the volume-changing material and the chip. In other words, the volume-changing material and the sealing material are selected so as to satisfy the above-mentioned condition for adhesion. When the releasing agent is eliminated, the volume-changing material and the material on the surface of the chip are the “interface members” between the volume-changing material and the chip. Also, when the adhesive is eliminated, the volume-changing material and the material on the sealing material are “interface members” between the volume-changing material and the sealing material.

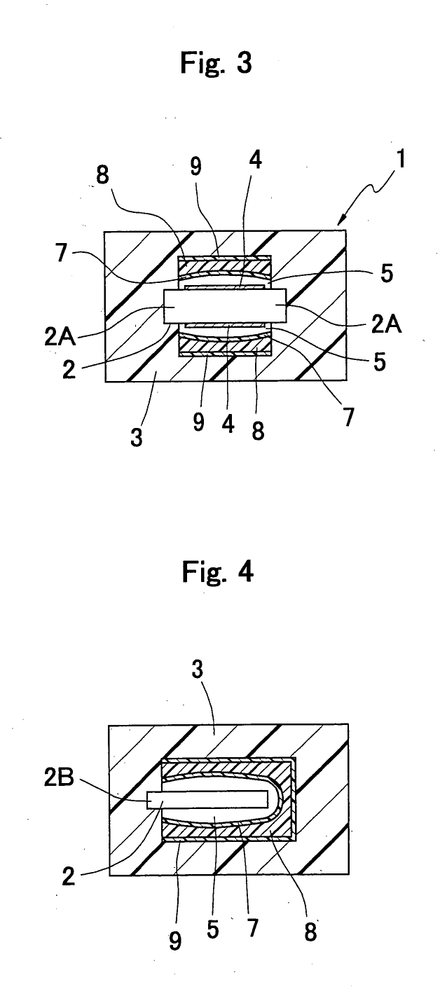

In case where the chip is a quartz oscillator, the resonance energy is localized in the middle of the quartz chip. Therefore, as illustrated in FIG. 3, the chip 2 preferably has a pair of end portions embedded in the sealing material 3, that is, the chip 2 is supported at both end portions so that the upper and lower surfaces of the chip 2 confront the space 5. Thus, in the modification, the volume-changing material 8 is provided both on the upper and lower surfaces of the chip 2. Also, if necessary, the releasing agent 7 may be disposed between the volume-changing material 8 and the chip surfaces. Furthermore, the adhesive 9 may be disposed between the volume-changing material 8 and the sealing material 3. The chip 2 is molded with the sealing material 3 so that the end portions 2A of the chip 2 are embedded in the sealing material 3. Then, the space 5 is defined above the upper and lower surfaces of the chip 2 by means of any one of the aforementioned processes. Thus, the supported end portions of the chip 2 and the space can be formed simultaneously.

Alternatively, as shown in FIG. 4, the chip may be supported at one end portion (cantilevered). In the modification, one end portion 2B of the chip 2 is embedded in the sealing material 3 and the remaining region of the chip 2 is disposed within the volume-changing material 8. If required, the releasing agent 7 may be disposed between the volume-changing material 8 and the chip surface, and furthermore, the adhesive 9 may be disposed between the volume-changing material 8 and the sealing material 3. The chip 2 is molded with the sealing material 3 so that one end portion 2B of the chip 2 is embedded in the sealing material 3. Then, any one of the aforementioned processes is used to define the space 5 over the chip 2 except the region of the end portion 2B. Thus, the supported end portion of the chip 2 and the space 5 can be formed simultaneously. In addition, since the chip 2 is supported at one end portion 2B with the sealing material, the stress applied to the chip is minimized. Therefore, the packaged component can be expected to have a stable characteristic.

Embodiment 2.

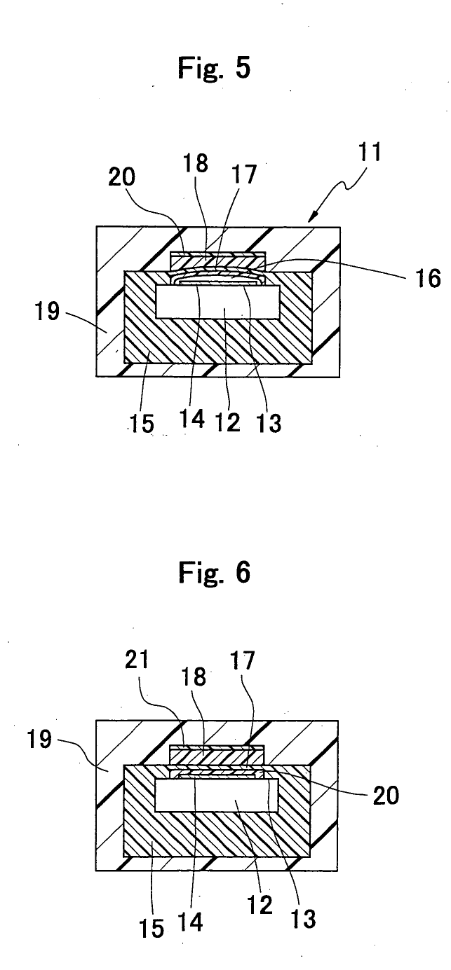

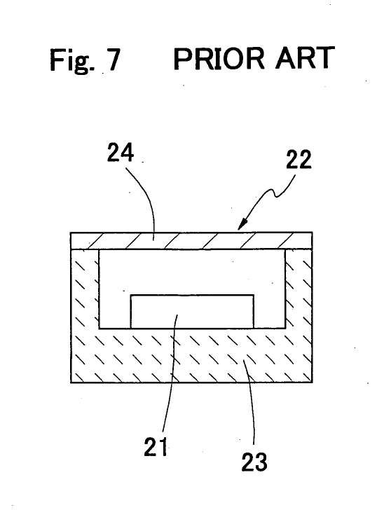

FIG. 5 is a cross sectional view of another packaged component of the present invention. The packaged component, denoted by reference numeral 11 as a whole, includes a function chip 12. The function chip 12 may be, for example, a SAW filter (Surface Acoustic Wave filter) including an electrode 14 with a predetermined pattern on one surface (upper surface 13 in the drawing). The chip 12 is sealed by molding with a first sealing material 15 of insulating material, and the space 16 is defined between the first sealing material and the chip upper surface 13. As illustrated, a cover layer 17 of the first sealing material 15 above the chip upper surface 13 is thin enough to readily deform when a force is applied to the cover layer. Also, the volume-changing material 18 is disposed on the cover layer 17 above the electrode 14 on the chip upper surface 13. Further, the chip 12, the first sealing material 15, and the volume-changing material 18 are sealed by molding with a second sealing material 19. Although not shown, the electrode 14 of the chip 12 is electrically connected via wires or lead frames to external terminals protruding from the peripheral surface of the second sealing material 19.

The packaged component 11 having such a structure is manufactured as described below. Firstly, as illustrated in FIG. 6, the chip 12 is sealed with the first sealing material 15. The cover layer 17 is formed of the sealing material to be thin on the upper surface 13 in the region covering the pattern electrode 14 of the chip 12. Next, the volume-changing material 18 is deposited on the cover layer 17. Then, the chip 12, the first sealing material 15, and the volume-changing material 18 are sealed with the second sealing material 19.

The space 16 may be formed by means of any manufacturing steps as described in the first embodiment, i.e., by heating the volume-changing material 18 of heat-shrinkable or heat-expandable material, radiating electromagnetic wave to the volume-changing material 18 of material reactive to electromagnetic wave, and using the volume-changing material 18 of chemically reactive material.

Preferably, the releasing agent 20 is provided between the cover layer 17 and the chip upper surface 13 so that the shrinkage of the volume-changing material releases the cover layer 17 from the chip upper surface 13 to define the space 16 over the pattern electrode 14. Thus, the first sealing material of the cover layer 17, the material forming the chip upper surface 13, and the releasing agent 20 are selected such that the releasing agent 20 together with the cover layer 17 separates from the chip upper surface 13.

Also, if desired to facilitate the cover layer 17 to separate from the chip upper surface 13 when the volume-changing material 18 shrinks, the adhesive 21 may be applied between the volume-changing material 18 and the cover layer 17 with adhesion greater than that between the releasing agent 20 and the cover layer 17.

In order to secure that the volume-changing material 18 shrinks while kept being supported by the second sealing material 19, each of those materials is selected such that the adhesion between the volume-changing material 18 and the second sealing material 19 (or the adhesive therebetween if any) is greater than that between the cover layer 17 and the chip upper surface 13.

In the packaged component so structured, the cover layer 17 between the chip 12 and the volume-changing material 18 eliminates a fragment of the volume-changing material 18 falling onto the chip 12, and seals the space 16 from gas harmful to the chip which may be generated from the volume-changing material 18, thereby to secure the stable characteristic of the chip 12.

Embodiment 3.

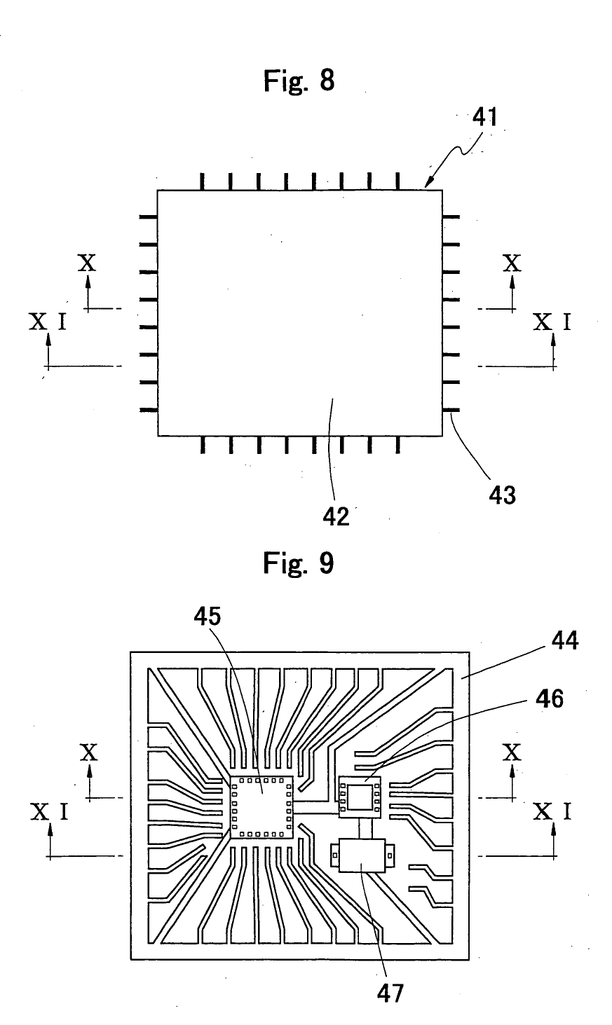

Referring to FIGS. 8 through 11, the third embodiment will be described herein. FIG. 8 is a top plan view of the packaged component 41, which includes a package 42 of insulating material and a plurality of external connection terminals 43 protruding externally from side surfaces of the package 42. As illustrated in FIG. 9, provided inside the package 42 are several chips and a lead frames 44 used for manufacturing the packaged component 41. Such several chips include a semiconductor integrated circuit chip 45 formed of a silicon substrate, a SAW filter chip 46 formed of a quartz crystal substrate of piezoelectric material, and a quartz oscillator chip (piezoelectric material chip) 47.

The lead frames 44 may be produced by pressing or etching a metal plate. Those chips are arranged on predetermined positions of the lead frames 44 and electrically connected to the lead frames 44 via metal wires (not shown). The lead frames 44 and those chips 45, 46, 47 properly arranged thereon are set onto the molding die (not shown). Then, the insulating resin material is injected into the molding die to form the package 42 encompassing those chips 45, 46, 47. Lastly, portions of the lead frames 42 externally protruding from the package 42 are cut off at the predetermined positions to form the external connection terminals 43 as shown in FIG. 8.

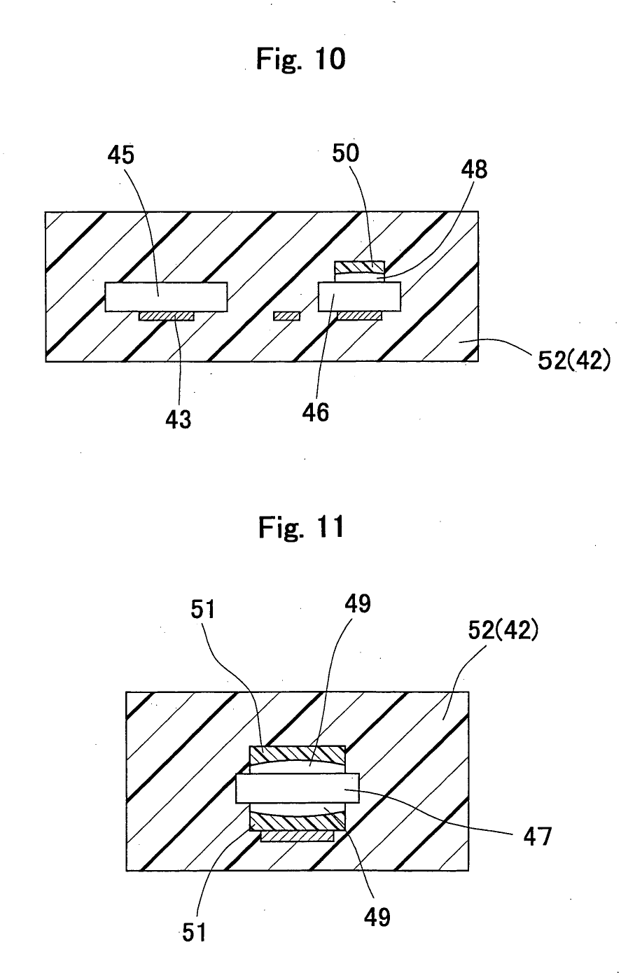

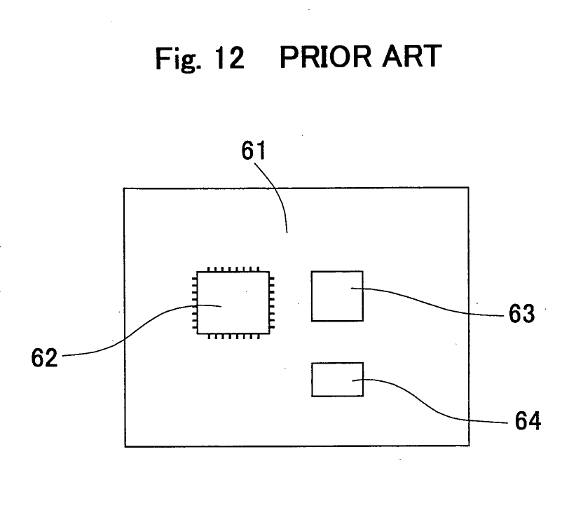

FIGS. 10 and 11 are cross sectional views of the package 42. As shown in the drawings, the semiconductor integrated circuit chip 45 is electrically connected to the connection terminals 43. Also, the SAW filter chip 46 and the quartz oscillator chip 47 are electrically connected to the respective ones of the connection terminals 43. However, unlike the semiconductor integrated circuit chip 45, the upper surface of the SAW filter chip 46 faces the space 48 (FIG. 10), and upper and lower surfaces of the quartz oscillator chip 47 having electrodes thereon confront the space 49 (FIG. 11).

The space 48 over the upper surface of the SAW filter chip 46 may be formed by applying the volume-changing material 50 on the upper surface and by shrinking the volume-changing material 50, as described in the first embodiment with reference of FIG. 2. Also, similar to the modifications of the first embodiment shown in FIG. 3, the space 49 defined over the upper and lower surfaces of the quartz oscillator chip 47 may be structured by applying the volume-changing material 51 on the upper and lower surfaces and heating to shrink the volume-changing material 51. Also, as described above in the first embodiment, the volume-changing material 51, the material on the chip surface in contact with the volume-changing material 51, and the sealing material 52 are selected such that when the volume-changing material 50, 51 shrinks, the volume-changing material 50, 51 releases from the chip surface while attaching to the sealing material 52 so as to form the space 48, 49.

Also, similar to the first embodiment, the releasing agent layer may be disposed between the volume-changing material and the chip surface, and/or the adhesive layer may be disposed between the volume-changing material and the sealing material layer.

Further, as described in the first embodiment, the volume-changing material may be either one of the heat-shrinkable/heat-expandable material, the electromagnetic-wave reactive material, and the chemically reactive material.

As above, major elements of a radio communication device including the semiconductor integrated circuit chip, the SAW chip, and the quartz oscillator chip, are accommodated within one package according to the third embodiment. This reduces the size of the radio communication device. Also, since the sealing step with resin material is achieved with well known art, the packaged component can be manufactured at a reasonable cost.

It should be noted that although those chips are mounted on the lead frames in the foregoing description, the chips may be mounted on an insulating board with terminals for electrical connection of the external connection terminals or the wires.

Also, the external connection terminals may be directly connected to the electrode pads on the chips.

Further, the piezoelectric material chip may be deposited on the semiconductor integrated circuit chip for the electrical connection.

Even further, although the SAW filter chip and the quartz oscillator chip are used as the piezoelectric material chips in the foregoing description, other piezoelectric material chips may be used such as a SAW oscillator chip, a quarts filter chip, and a ceramic filter chip.

Also, in addition to the semiconductor integrated circuit chip, a dielectric element such as a dielectric filter chip may be incorporated in the packaged component.

To this end, various types of integrated circuits having multiple functions can be produced by incorporating various chips.

Embodiment 4.

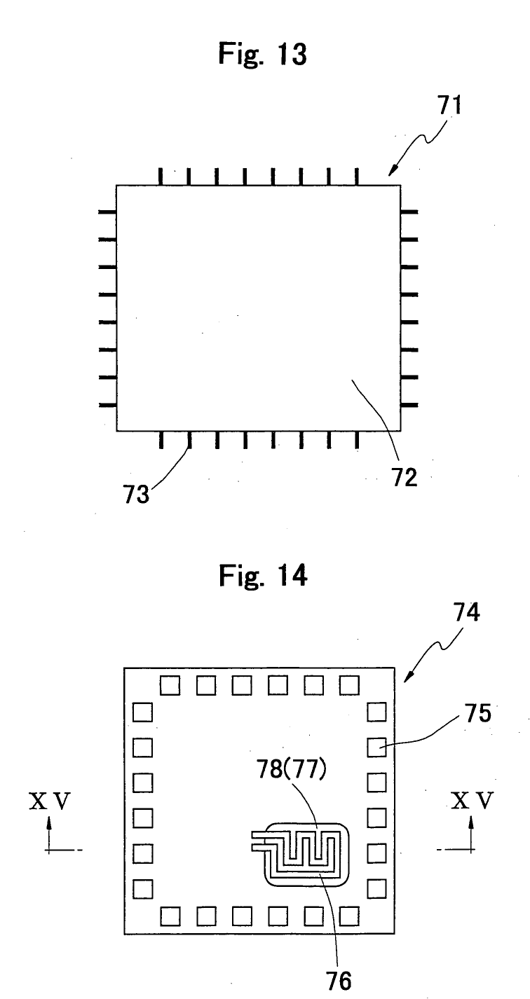

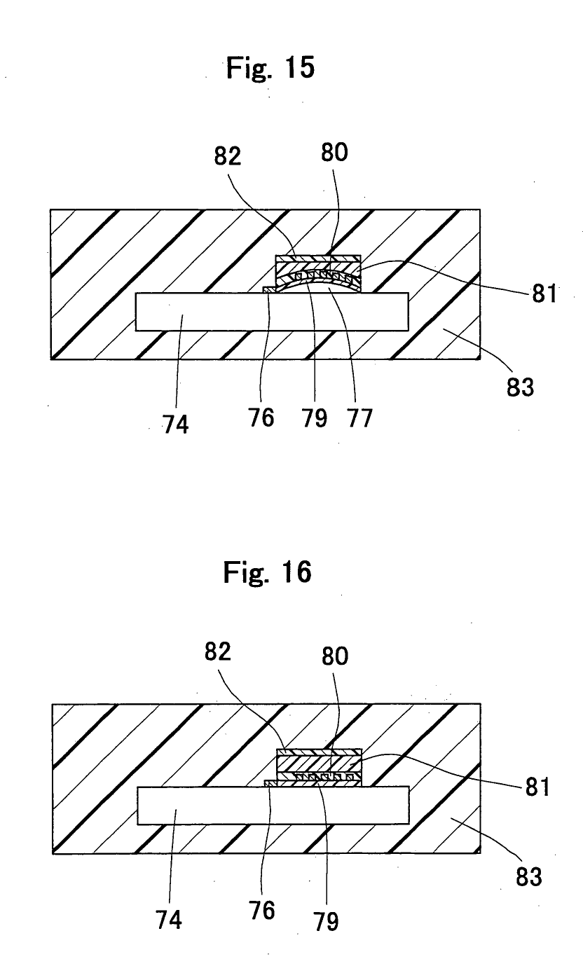

Referring to FIGS. 13 through 15, the fourth embodiment will be described herein. FIG. 13 is a top plan view of the packaged component 71, which includes a package 72 made of insulating material and a plurality of external connection terminals 73 protruding externally from the side surfaces of the package 72. As illustrated in FIGS. 14 and 15, a semiconductor integrated circuit chip 74 is provided within the packaged component 71, and each of the electrode pads 75 on the semiconductor integrated circuit chip 74 is electrically connected to the respective one of the external connection terminals 73.

The semiconductor integrated circuit chip 74 has a coil pattern 76 of conductive metal on the upper surface for oscillating a high-frequency signal. Also, the space 77 is defined between the coil pattern 76 and the semiconductor integrated circuit chip 74 so that the high-frequency signal generated from the coil pattern 76 is not damped.

The space 77 is produced by the steps described below. As illustrated in FIG. 16, the releasing agent 79 is applied on the surface of the semiconductor integrated circuit chip 74 in the region 78 (see FIG. 14), above which the space 77 will be defined. Then, the coil pattern 76 is formed on the releasing agent 79 by means of a semiconductor manufacturing process. However, as shown, both of the terminals of the coil pattern 76 are formed directly on the surface of the semiconductor integrated circuit chip 74 so as to electrically connect the circuit thereof (not shown). Next, a first adhesive 80 is applied on the coil pattern 76 in the region 78. Then, the volume-changing material 81 is deposited on the first adhesive 80. Subsequently, a second adhesive 82 is applied on the volume-changing material 81. The semiconductor integrated circuit chip 74 is sealed with the insulative sealing material 83. It should be noted that the semiconductor integrated circuit chip 74 is electrically connected with the external connection terminals 73 before they are sealed with the sealing material 83. Lastly, the volume-changing material 81 is heated to shrink so that the shrinkage separates the coil 76 from the semiconductor integrated, circuit chip 74 and defines the space 77 therebetween.

When forming the space 77, the adhesion is exerted at the interfaces, i.e., between the first adhesive 80 and the semiconductor integrated circuit chip 74, between the first adhesive 80 and the volume-changing material 81, between the second adhesive 82 and the volume-changing material 81, and between the second adhesive 82 and the sealing material 83. However, since the releasing agent 79 is provided between the first adhesive 80 and the semiconductor integrated circuit chip 74, the adhesion thereof is much less than those of the first and second adhesive 80, 82. Therefore, the shrinkage of the volume-changing material 81 readily releases the coil pattern 76 and the first adhesive 80 from the semiconductor integrated circuit chip 74, thereby to define the space 77.

Also, as described in the first embodiment, the volume-changing material may be either one of the heat-shrinkable/heat-expandable material, the electromagnetic-wave reactive material, and the chemically reactive material.

Thus, since the coil pattern can be formed away. from the surface of the semiconductor integrated circuit chip according to the fourth embodiment, the attenuation of the high-frequency signal generated from the coil pattern is reduced, therefore, the Q-value is increased.

Embodiment 5.

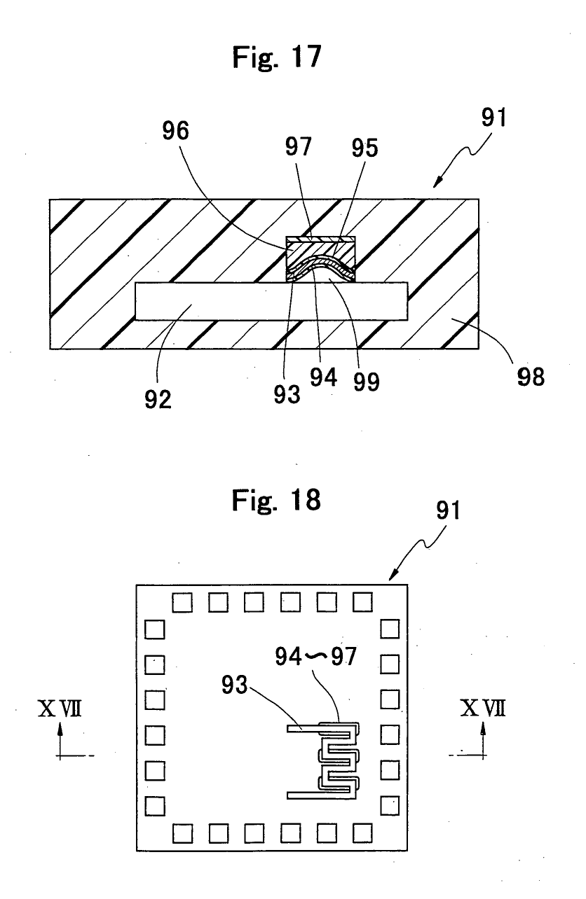

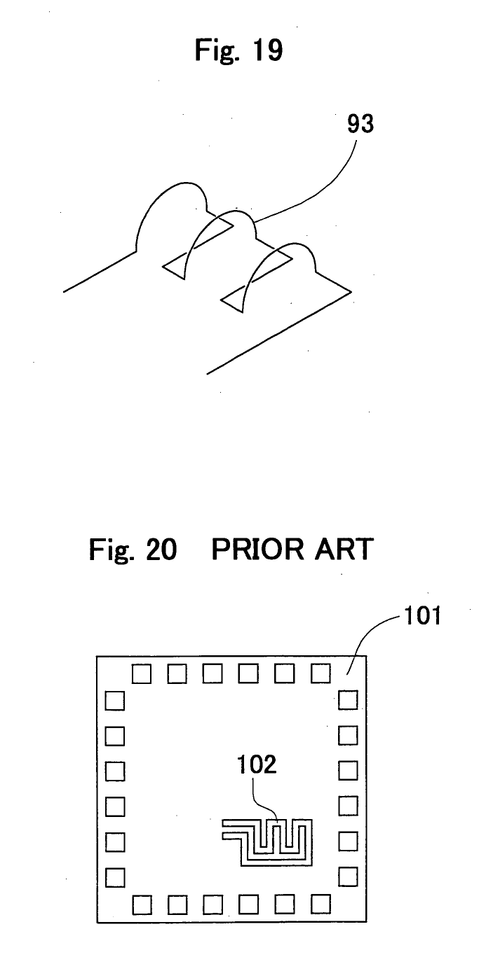

Referring to FIGS. 17 through 19, the fifth embodiment will be described herein. FIG. 17 is a cross sectional view of the packaged component 91 according to the fifth embodiment, and FIG. 18 is a top plan view of a semiconductor integrated circuit chip (first element) 92 built in the packaged component 91. As illustrated in those drawings, the packaged component 91 of the present embodiment is a modified one of the fourth embodiment, in which the coil pattern (second element) 93 on the surface of the semiconductor integrated circuit chip 92 is formed to have a meander shape like a continuous rectangular pulse. In this embodiment, the volume-changing material is applied only on limited regions, not on the whole region of the coil pattern. Thus, the coil pattern has a plurality of lines (portions) extending a right-left direction in FIG. 18, the releasing agent 94 and the adhesive 95 are applied under and on alternate lines (every second lines) of the coil pattern, respectively. Then, the volume-changing material 96 and the second adhesive 97 are applied only on the regions on which the first adhesive 95 are applied. The semiconductor integrated circuit chip 92 is sealed with the sealing material 98 (see FIG. 17.) after the electrode pads thereof are electrically connected to the external connection terminals (not shown). Then, the volume-changing material 97 is heated to shrink so that the shrinkage releases the alternate lines of the coil pattern away from the semiconductor integrated circuit chip 92, thereby to define the space 99. To this end, the coil on the surface of the semiconductor integrated circuit chip 92 is formed to have a three dimensional helical structure as illustrated in FIG. 19. The current through the tri-dimensional coil 93 generates a magnetic field in an up-down direction in FIG. 18.

When the coil is driven to generate the magnetic field, the current is flown through the semiconductor integrated circuit chip 92 due to the electromagnetic induction effect. The semiconductor substrate of the semiconductor integrated circuit chip 92 has a resistance component, which could damp the Q-value of the coil 93. However, according to the present embodiment, since the axis of the coil 93 is parallel to the surface of the semiconductor integrated circuit chip 92, the magnetic field generated from the coil 93 will not be localized on the surface of the semiconductor integrated circuit chip 92. Therefore, the magnetic field is less influenced by the resistance component of the semiconductor integrated circuit chip 92, which in turn causes the Q-value of the coil 93 improved.

Conventionally, a multi-layer technology of the semiconductor process may be used to form the tri-dimensional coil structure, however, the wire layer cannot be thickened without limit. Therefore, the Q-value of the coil structure produced by the conventional multi-layer technology is likely reduced due to the attenuation by the semiconductor integrated circuit chip, which would be approximately 10 at most.

Contrary, according to the present embodiment, the deformation of the volume-changing material can produce the coil having the three dimensional structure, of which Q-value can be improved up to approximately 20.

In the foregoing description, although the coil is described as an example of the element of the tri-dimensional structure, it is not limited thereto and any other elements can be produced as the tri-dimensional structure. For example, structures of a capacitance electrode, a strip line for transmitting the high-frequency signal, a wave guide, a cavity oscillator, and any other structures required for various sensors can be achieved. Also, an antenna of the semiconductor integrated circuit having a function of a radio communication device can be produced by means of the aforementioned process for manufacturing the three dimensional structure.

In addition, where the volume-changing material has elasticity after shrinking, an impact detecting sensor can be produced with use of the coil or capacitance having the tri-dimensional structure. In the impact detecting sensor, the elasticity of the volume-changing material allows vibration (shrinkage and expansion) of the material upon receiving an external impact. It changes the size of the coil or capacitance, and thus, the voltage or capacitance across the coil or the capacitance is varied, which can be detected by applying current through the coil or voltage across the capacitance.

Further, according to the present embodiment, when the semiconductor integrated circuitry has a particular region, over which the volume-changing material is deposited, the region of the semiconductor integrated circuitry can be exposed to the atmosphere by abrading the volume-changing material after it shrinks. For instance, when a sensor such as a CMOS image pickup sensor is integrated on the semiconductor integrated circuit chip, only the sensor region can be exposed to the atmosphere.

1-18. (Cancelled)

19. A manufacturing process of a packaged component, comprising:
(a) preparing an element;
(b) depositing a volume-changing member on at least a partial surface of said prepared element;
(c) sealing said element and said volume-changing member with a sealing material;
(d) shrinking said volume-changing member sealed with said sealing material to release said volume-changing member from the partial surface of said element opposing thereto, thereby to define a space therebetween.

20. The process according to claim 19,
wherein said volume-changing member is made of material that shrinks when heated; and
wherein the step (d) is made by heating to shrink said volume-changing member.

21. The process according to claim 19,
wherein said volume-changing member is made of material that expands when heated;
wherein the step (c) is made while said volume-changing member is heated for expansion; and
wherein the step (d) is made by cooling to shrink said volume-changing member heated in the step (c).

22. The process according to claim 19,
wherein said volume-changing member is made of material that shrinks when exposed to a electromagnetic wave; and
wherein the step (d) is made by radiating the electromagnetic wave to said volume-changing member.

23. The process according to claim 19,
the step (b) including,
applying a releasing agent between said volume-changing member and the partial surface of said element opposing thereto,
applying said volume-changing member on said releasing agent, and
applying an adhesive between said volume-changing member and said sealing material opposing thereto.

24. A manufacturing process of a packaged component, comprising:
(a) preparing an element;
(b) forming a cover layer on at least a partial surface of said prepared element;
(c) depositing a volume-changing member on said cover layer;
(d) sealing said element, said cover layer, and said volume-changing member with a sealing material;
(e) shrinking said volume-changing member sealed with said sealing material to release said volume-changing member from the partial surface of said element opposing thereto, thereby to define a space therebetween.

25. A manufacturing process of a packaged component, comprising:
(a) preparing a semiconductor integrated circuit chip and a piezoelectric material chip;
(b) arranging said semiconductor integrated circuit chip and said piezoelectric material chip at predetermined positions;
(c) electrically connecting said semiconductor integrated circuit chip and said piezoelectric material chip to external connection terminals;
(d) depositing a volume-changing member on at least a partial surface of said piezoelectric material chip;
(e) sealing said semiconductor integrated circuit chip and said piezoelectric material chip with a sealing material after the steps (c) and(d); and
(f) shrinking said volume-changing member sealed with said sealing material to define a space between said volume-changing member and the partial surface of said piezoelectric material chip.

26. A manufacturing process of a packaged component, comprising:
(a) preparing a first element;
(b) providing a second element on a surface of said first element;
(c) depositing a volume-changing member on said second element;
(d) sealing said first and second elements and said volume-changing member with a sealing material; and
(e) shrinking said volume-changing member to release said second element from said first element.
